(19) United States
(12) Patent Application Publication
(10) Pub. No.: US 2025/0143061 A1
(43) Pub. Date: May 1, 2025

(54) MOLECULAR DIODE UTILIZING THE CHARACTERISTIC OF INDUCING ELECTRICALLY INACTIVE ORGANIC MOLECULES INTO MOLECULES WITH ELECTRICAL PROPERTIES

(71) Applicant: Korea University Research and Business Foundation, Seoul (KR)

(72) Inventors: Hyo Jae YOON, Seoul (KR); Gyudon KONG, Seoul (KR)

(73) Assignee: Korea University Research and Business Foundation, Seoul (KR)

(21) Appl. No.: 18/885,073

(22) Filed: Sep. 13, 2024

(30) Foreign Application Priority Data
Sep. 13, 2023 (KR) 10-2023-0121483
Sep. 10, 2024 (KR) 10-2024-0123142

(51) Int. Cl. H10K 10/00; H10K 10/20; H10K 85/60

(52) U.S. Cl. CPC H10K 10/701; H10K 10/20; H10K 85/60

(57) ABSTRACT

Disclosed is a molecular diode using the assignment of electrical properties to inactive organic molecules when a self-assembled monolayer (SAM) thin film including an electrically inactive organic molecule is formed without synthesizing a separate organic molecule having electrical activity. The disadvantage of the instability of a conventional SAM can be overcome, a function can be extended, and electrical properties, such as a rectification characteristic in a non-functional molecule, can be induced even without the design and synthesis of organic molecules for introducing a functional molecule. Accordingly, the embodiments of the present disclosure can be usefully used in various technical fields in which an SAM is used, in particular, wide fields such as electronics, an organic display (OLED), solar cells, sensors, non-uniform catalysts, frictional electricity, cell growth surfaces, and a heat transfer control film.

### BACKGROUND

### 1. Technical Field

The present disclosure relates to a molecular diode including a self-assembled monolayer (SAM) thin film, and more particularly, to a molecular diode using the assignment of electrical properties to inactive organic molecules when an SAM thin film including an electrically inactive organic molecule is formed without synthesizing a separate organic molecule having electrical activity.

### 2. Related Art

A self-assembled monolayer (SAM) thin film is a nano substance for surface structure control, which is widely used in many fields, such as biotechnology, diagnostics, and energy engineering in addition to molectronics. The SAM may be easily damaged by an external stimulus because the SAM basically consists of organic molecules and generates a hyper-thin thin film of several nano meters.

In the molecular electronics, the amount of current that flows through a molecular junction is determined depending on whether a molecular orbital energy level enters a transmission window. If the molecular orbital energy level does not enter the transmission window, a current flows on the basis of off-resonant tunneling. If the molecular orbital energy level enters the transmission window, a current flows on the basis of resonant tunneling and shows a relatively high current value. A molecular diode may be designed based on such a principle (FIG. 7).

The induction of diode characteristics in the molecular diode depends on whether the molecular orbital energy level is included in the transmission window as described above as illustrated in FIG. 7.

In this case, there is a method of designing molecules so that the molecules having activity having an accessible energy level are designed. There is another method of achieving the design of the molecules by extending the transmission window. The former approach method is performed so far in many researches. However, in this case, there is a problem in that the stability of the SAM is reduced when a high voltage is applied because a breakdown voltage is lowered due to a defect of components of an active molecule.

Furthermore, in order to avoid such a problem, various researches, such as research for designing and synthesizing various molecules having electrical activity so that the stability of the SAM can be increased and research for increasing the stability of the SAM by changing the components of the SAM, are carried out. However, there is a problem in that complicated organic synthesis is essentially involved in order to introduce the electrical activity.

The inventors of the present disclosure also carried out research for increasing the stability of the SAM in various ways. A technique for manufacturing a heterogeneous supermolecular-mixed SAM thin film having a controlled ultra molecular structure based on a repeated surface exchange of molecules (ReSEM) so that the heterogeneous supermolecular-mixed SAM thin film can withstand a high voltage by removing an ultra molecule defect within the SAM was recently reported (Korean Patent Application Publication No. 10-2023-0128691, Sep. 5, 2023). However, the method has a problem in that complicated organic synthesis for molecule having electrical activity is inevitably involved.

The inventors of the present disclosure confirmed that a high rectification characteristic could be assigned to molecules even at a high voltage, non-functional molecules could also be electrically induced into functional molecules without organic synthesis for enabling the molecules to have electrical activity, specially, by manufacturing an SAM based on the ReSEM and a molecular diode could be implemented by using such a method, and completed embodiments of the present disclosure.

### SUMMARY

Various embodiments are directed to providing a molecular diode using electrically inactive organic molecules that are structurally simple and accessible without the need to synthesize a complicated molecule structure so that molecules have electrical activity.

Also, various embodiments are directed to providing a molecular junction system which assigns electrical properties to electrically inactive organic molecules and also has high electrical stability by forming a heterogeneous mixed self-assembled monolayer (SAM) thin film along with the electrically inactive organic molecules by using a repeated surface exchange of molecules (ReSEM) method.

In an embodiment, there is provided a heterogeneous supramolecular-mixed SAM thin film including a plurality of matrix molecules that is adjacently arranged in parallel and a reinforcement molecule packed between the plurality of matrix molecules.

Each of the matrix molecule and the reinforcement molecule is a molecule not having electrical activity. The matrix molecule may be represented by Chemical Formula 1. The reinforcement molecule may be represented by Chemical Formula 2.

HS—(CₙH₂ₙ₊₁)—COOH [Chemical Formula 1]

HS—(CₘH₂ₘ₊₁) [Chemical Formula 2]

In Chemical Formula 1 and Chemical Formula 2, each of n and m is an integer of 1 to 20, wherein n>m.

The heterogeneous supramolecular-mixed SAM thin film according to an embodiment of the present disclosure is formed through a repeated surface exchange of molecules (ReSEM) process.

In this case, when the heterogeneous supramolecular-mixed SAM thin film is formed through the ReSEM process, the matrix molecule has electrical activity and a rectification characteristic.

According to an embodiment of the present disclosure, the matrix molecule represented by Chemical Formula 1 may be HS—(C₁₅H₃₁)—COOH, and the reinforcement molecule represented by Chemical Formula 2 may be HS—(C₁₂H₂₅).

The heterogeneous supramolecular-mixed SAM thin film according to an embodiment of the present disclosure is formed through the ReSEM, and is formed by including the following steps:

(I) a step of forming a self-assembled monolayer (SAM) composed of the matrix molecule on a substrate by using the matrix molecule represented by Chemical Formula 1,

HS—(CₙH₂ₙ₊₁)—COOH [Chemical Formula 1]

(II) a step of forming an intermediate-mixed SAM by inducing a substitution reaction within a surface of the SAM by dipping the SAM produced through the step (I) in a solution of the reinforcement molecule represented by Chemical Formula 2,

HS—(CₘH₂ₘ₊₁) [Chemical Formula 2]

(III) a step of forming an interstitial-mixed SAM having packing enhanced by dipping the intermediate-mixed SAM formed through the step (II) into the solution of the matrix molecule, and

(IV) a step of forming an interstitial-mixed SAM thin film having an ultra molecular defect minimized by inducing n ReSEM cycles by repeating the steps (II) to (III) n times (wherein the n is an integer equal to or greater than 2);

In Chemical Formula 1 and Chemical Formula 2, each of n and m is an integer of 1 to 20, wherein n>m.

According to an embodiment of the present disclosure, the substrate is a flat template-stripped metal chip, and may be Au^{TS}, Ag^{TS} or Pt^{TS} according to an embodiment of the present disclosure.

Furthermore, an embodiment of the present disclosure provides a molecule electronic device including an upper electrode, a lower electrode that faces the upper electrode, and a molecular layer formed on the lower electrode, wherein the molecular layer is the heterogeneous supramolecular-mixed SAM thin film according to an embodiment of the present disclosure.

According to an embodiment of the present disclosure, the upper electrode is a liquid metal eutectic gallium-indium (EGaIn) alloy-based electrode.

According to an embodiment of the present disclosure, the size of a breakdown voltage (V_{BD}) of the molecule electronic device may be |2.0 V| to |4.6 V|.

According to an embodiment of the present disclosure, the molecule electronic device may be a molecule rectification device that performs a molecular rectification action.

Furthermore, according to an embodiment of the present disclosure, the molecule electronic device having a large area molecular junction can be manufactured by using a liquid metal eutectic gallium-indium (EGaIn) liquid metal-based electrode. In this case, the EGaIn liquid metal forms a thin (up to 1 nm) gallium oxide (Ga₂O₃) film on a surface when exposed to the air. Such an oxide film enables several hundreds of to several thousands of tunneling data to be secured per junction within a relatively short time with yield of 80% or more even in a common atmospheric environment.

Furthermore, in the molecule electronic device according to an embodiment of the present disclosure, if a technique called template-stripping is used, the roughness of a metal subelectrode can be controlled. Accordingly, the roughness of a manufactured gold electrode (Au^{TS}) will have a very flat surface of up to 0.2 nm level.

According to the embodiments of the present disclosure, unlike a conventional molecule electronic device in which complicated organic synthesis is essentially accompanied in order to introduce electrical activity, the molecular diode using non-functional molecules as functional molecules can be provided even without special organic synthesis. In the molecular diode according to an embodiment of the present disclosure, a rectification characteristic is induced through the non-functional molecules, and applied to the molecular diode.

Furthermore, the molecular junction including the heterogeneous supramolecular-mixed SAM thin film according to an embodiment of the present disclosure can significantly improve electrical stability, and has excellent stability because the molecular junction can withstand a high voltage. The molecular diode including the molecular junction according to an embodiment of the present disclosure has excellent electrical stability because the molecular diode can have a high breakdown voltage.

Accordingly, if the embodiments of the present disclosure are used, the disadvantage of the instability of a conventional SAM can be overcome, a function can be extended, and electrical properties, such as a rectification characteristic in a non-functional molecule, can be induced even without the design and synthesis of organic molecules for introducing a functional molecule. Accordingly, the embodiments of the present disclosure can be usefully used in various technical fields in which an SAM is used, in particular, wide fields such as electronics, an organic display (OLED), solar cells, sensors, non-uniform catalysts, frictional electricity, cell growth surfaces, and a heat transfer control film.

### BRIEF DESCRIPTION OF THE DRAWINGS

FIGS. 1A, 1B and 1C are schematic diagrams illustrating two strategies for charge tunneling control in the molecular electronics. FIG. 1A illustrates a strategy in which a molecular orbital energy level is pushed into a transmission window. FIG. 1B illustrates a strategy in which a transmission window is extended so that the transmission window includes sub-HOMO and post-LUMO levels. FIG. 1C is a schematic diagram illustrating a chemical structure of a molecule that is used in a repeated surface exchange of molecules (ReSEM) process according to an embodiment of the present disclosure.

FIGS. 2A and 2B illustrate the results of the check of optimal SCₙ reinforcement molecules in an embodiment of the present disclosure. FIG. 2A is a plot of a breakdown voltage (V_{BD}) V according to the length of alkyl chains of reinforcement molecules and changes (2, 4, 6, 8, 10, 12, and 14) in the length of n of SCₙ in an SCₙ—HSC₁₅CO₂H heterogeneous mixed SAM that was formed through two cycles of the ReSEM process. It may be seen that the breakdown voltage (V_{BD}) of the heterogeneous mixed SAM that was processed by the ReSEM method according to an embodiment of the present disclosure is higher than that of a pure single HSC₁₅CO₂H SAM (a dotted line indicates the breakdown voltage of the pure HSC₁₅CO₂H SAM). FIG. 2B is a breakdown voltage (V_{BD}) histogram of a SAM in which the pure HSC₁₅CO₂H SAM and SC₁₂ were mixed.

FIGS. 3A, 3B and 3C illustrate the results of a comparison between the structures of a single HSC₁₅CO₂H SAM in Au^{TS} according to an experimental example of the present disclosure and the SC₁₂—HSC₁₅CO₂H heterogeneous mixed SAM formed by the ReSEM method according to an embodiment of the present disclosure. FIG. 3A illustrates a linear voltage current curve. FIG. 3B illustrates a C1s NEXAFS spectrum that was obtained at an X-ray incident angle of 55°. FIG. 3C illustrates IRRAS spectran in a C—H flexibility vibration region (2750 to 3100 cm⁻¹) of the single HSC₁₅CO₂H SAM in Au^{TS} and the SC₁₂—HSC₁₅CO₂H heterogeneous mixed SAM that was formed by the ReSEM method according to an embodiment of the present disclosure.

FIGS. 4A, 4B and 4C illustrate the measured data of a molecular junction according to an embodiment of the present disclosure. FIG. 4A illustrates histograms having a rectification rate. FIG. 4B illustrates a rectification trend. FIG. 4C illustrates a function of an external bias voltage for the SC₁₂—HSC₁₅CO₂H heterogeneous mixed SAM formed by the ReSEM method in Au^{TS} according to an embodiment of the present disclosure, and illustrates a log |J|−V plot.

FIG. 5A illustrates a comparison between experimental values and calculated values of log|r| for the molecular junction according to an embodiment of the present disclosure. FIG. 5B illustrates projection state densities that were obtained in molecular-projected self-consistent Hamiltonian (MPSH) analysis in a zero bias. FIGS. 5C and 5D illustrate transmission plots in low (|1.5 V|) and high (|2.5 V|) biases. FIG. 5E illustrates bias-dependent MO energy that was extracted from a transmission function, and illustrates that the bias-dependent MO energy does not appear because HOMO and HOMO-1 levels were merged into a HOMO-2 level at −1.0 V or less, a LUMO level was also merged into a LUMO+1 or LUMO+2 level at −1 V or less, and a yellow region shows a transmission window.

FIG. 6A illustrates chemical structures of molecules that are used as matrix molecules and reinforcement molecules in an embodiment of the present disclosure. FIG. 6B is a diagram of a process of manufacturing the SC₁₂—HSC₁₅CO₂H heterogeneous mixed SAM that was formed by the ReSEM method according to an embodiment of the present disclosure.

FIG. 7 is a diagram that describes a principle in which a transmission window is extended according to the application of a high voltage and a rectification characteristic is induced in the molecular electronics.

### DETAILED DESCRIPTION

Hereinafter, embodiments of the present disclosure are described more specifically.

The inventors of the present disclosure confirmed that the characteristic of an inactive molecule is changed into a highly adjustable rectification characteristic if the packing structure of a monolayer thin film layer is controlled through the mixing of heterogeneous molecules, and implemented a diode device based on such confirmation.

In an embodiment of the present disclosure, a heterogeneous mixed self-assembled monolayer (SAM) thin film layer including heterogeneous alkanthiolates that has or does not have a carboxylic acid head group may be formed through a surface exchange reaction using a repeated surface exchange of molecules (ReSEM) method.

In this case, the heterogeneous mixed SAM thin film layer according to an embodiment of the present disclosure shows electrical stability in which the heterogeneous mixed SAM thin film layer withstands a high voltage of a maximum of |4.5 V| and also shows a dynamic rectification characteristic in its size and polarity. This may be seen in a lower highest occupied molecular orbital (HOMO) level that is activated by a widened transmission window. Furthermore, it may also be seen that a new electrical characteristic is assigned to an electrically inactive organic molecule through only the mixing of a simple ultra molecule without the design or synthesis of an electrically active molecule.

An external bias voltage that is applied to a molecular junction generates a transmission window. An electrical function of the molecular junction is determined depending on whether a molecular orbital (MO) energy level enters the transmission window and the type and number of MOs. In a model of a transmission function based on an energy level having a Lorentz form, a current that flows through transmission window is different depending on a degree of overlapping between the MO energy level and the transmission window.

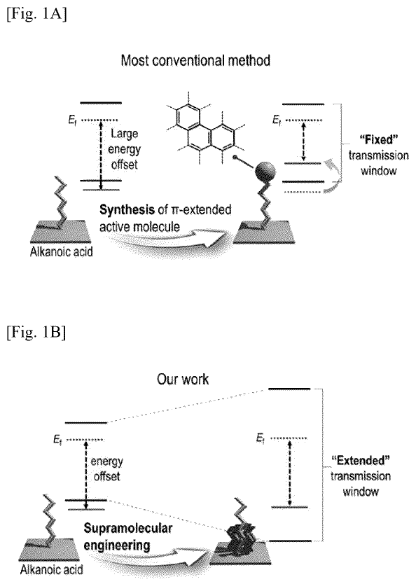

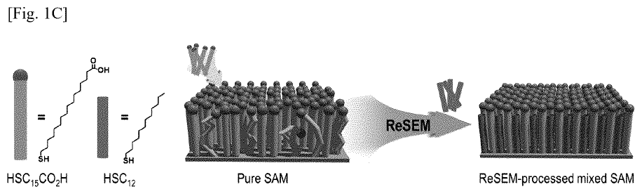

In order to develop the molecular junction having the electrical function, so as to guarantee that the MO energy level enters or exits from the transmission window as a function of an external voltage, the first approach is a method of pushing the MO energy level into the transmission window (FIG. 1A), and the second approach is a method of widening the transmission window while maintaining the structure of a molecule without any change.

Conventionally, the first approach is common despite significant synthesis overhead that is necessary to find an optimized structure. In order to achieve the first approach, researchers introduced an i-extended building block or metal complex into an electrically active molecule of a molecular junction as illustrated in FIG. 1A. Such a structure is close to the Fermi level and generates a frontier MO energy level (the highest occupied molecular orbital (HOMO) level) or the lowest unoccupied molecular orbital (LUMO) level) having a high probability that the MO energy level will enter the transmission window (FIG. 1A).

The second approach is a method according to an embodiment of the present disclosure and has been rarely reported so far. The second approach can increase a breakdown voltage by improving electrical stability without modifying the structure of a molecule, and can activate a sub-HOMO and/or a post-LUMO level by using an extended transmission window (FIG. 1B).

As described above, a molecular diode to which electrical properties have been assigned can be implemented by using a structurally simple and accessible molecule without the need to synthesize a complicated molecule structure so that molecules have electrical activity according to embodiments of the present disclosure.

Furthermore, recently, the inventors of the present disclosure developed an ultra molecular mixing method called a repeated surface exchange of molecules (ReSEM) when a mixed self-assembled monolayer (SAM) capable of withstanding a high external voltage is formed. It was found that such an ReSEM-processed mixed SAM showed a further strong and higher breakdown voltage compared to a single component. Accordingly, in embodiments of the present disclosure, the transmission window can be widened without deteriorating the function of a corresponding SAM.

Furthermore, in embodiments of the present disclosure, a very wide transmission window may be generated by activating sub-HOMO through an ReSEM process.

According to an embodiment of the present disclosure, a dynamic molecule rectification device can be implemented (FIG. 1C) by using a structurally simple and common organic compound, such as mercaptohexadecanoic acid (HSC₁₅CO₂H) and n-dodecanethiol (HSC₁₂).

Furthermore, a heterogeneous mixed SAM that is formed of HSC₁₅CO₂H and HSC₁₂ through an ReSEM process shows a high breakdown voltage of a maximum of |4.5 V|. A rectification-voltage relation can be seen in a wide voltage range.

As in Equation (1), a rectification rate (r) is defined as a quotient of the current density (J, A/cm²) that is measured at +V and −V in the same junction.

$$r = \vert J ( + V ) \vert / \vert J ( - V ) \vert \qquad Equation ( 1 )$$

In the case of |J(+V)|>|J(−V)|, a molecule is rectified to have a positive polarity, wherein r>1 (log |r|>0). In the case of |J(−V)|>|J(+V)|, the rectification of a molecule has a negative polarity, wherein r<1 (log |r|<0).

The heterogeneous mixed SAM according to an embodiment of the present disclosure shows a dynamic change of the rectification of a molecule in its size and polarity as a function of a voltage. Neglectable rectification (r≈2) is monitored in a low voltage region (|1.0 V|). As the voltage is increased to |1.5V|, the rectification is slightly increased to a positive polarity (r≈5). When the voltage is further increased, the rectification disappears at |2.0V|, and high rectification (r≈0.005; 1/r≈200) having the polarity inverted appears at |3.0V|. A change in the size and polarity of rectification of a molecule, which is caused by a bias, through the calculation of a periodic density functional theory (DFT) is caused by a widened transmission window which enables a sub-HOMO level to enter the widened transmission window and to participate in the transport of charges.

The heterogeneous mixed SAM according to an embodiment of the present disclosure is formed by using two types of molecules, that is, a functional matrix molecule and a reinforcement molecule that serves to improve the structural stability of an SAM by the ReSEM process.

According to an embodiment of the present disclosure, HSC₁₅CO₂H and HSCₙ (wherein n=2, 4, 6, 8, 10, 12 or 14) are used in the matrix and reinforcement molecules, respectively. HSCₙ plays a role as an effective reinforcement molecule for filling a pinhole defect of an SAM attributable to a thin structure. HSC₁₅CO₂H is used in the matrix molecule.

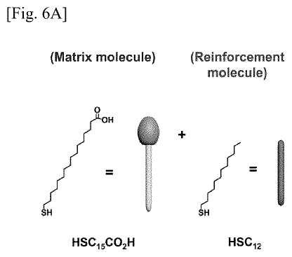

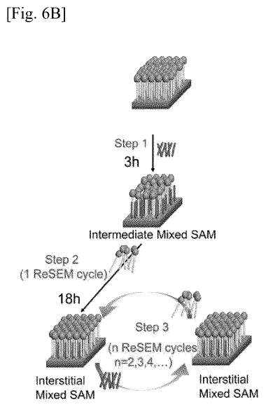

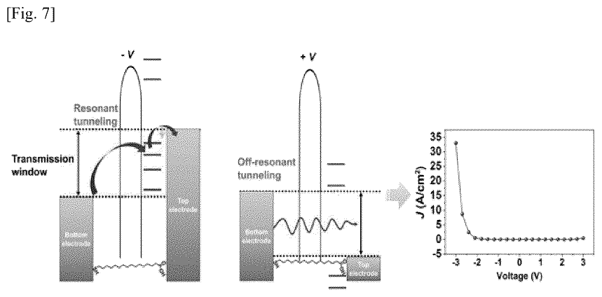

An embodiment of the present disclosure illustrated in FIG. 6B is described as follows.

First, a molecule to be used as the matrix molecule is an organic molecule (named an HSC₁₅CO₂H molecule) which has an alkyl chain having 15 lengths as a framework and a carboxylic group as an end group, and is known as a non-functional molecule that has been widely researched in a range of about 1 V in the existing research and that does not have rectification. A very stable thin film can be manufactured by using the molecule through the ReSEM process because the molecule enables a high lateral interaction due to a hydrogen bond between carboxylic groups of end groups when the molecule is manufactured as an SAM.

Furthermore, the reinforcement molecule is a molecule that does not show a rectification characteristic and improves an ultra molecular structure stability of an SAM simply and structurally, and is an n-alkanethiolates (n=2, 4, 6, 8, 10, 12, 14) molecule (wherein n refers to the length of an alkyl chain).
(I) A step of forming an SAM by introducing the HSC₁₅CO₂H molecule on a template-stripped gold surface (Au^{TS}) that is specially manufactured so that the HSC₁₅CO₂H molecule has a flat surface.
(II) A step of inducing a substitution reaction within the surface by dipping the SAM produced in the step (I) into an HSC₁₂ solution.

An intermediate-mixed SAM is formed through the step (II).
(III) A step of dipping a thin film in an intermediate step, which was produced through the step (II), in an HSC₁₅CO₂H solution again.

A interstitial-mixed SAM having packing enhanced is formed through the step (III), which is named a “1 ReSEM cycle”.
(IV) Thereafter, a step of manufacturing a gap type mixed SAM thin film having an ultra molecular defect minimized by unlimitedly repeating the steps (II) to (III) (n ReSEM cycles, n=2, 3, 4 . . . ).

The gap type mixed SAM thin film does not show significant rectification at a low voltage (≤1.0 V) because the gap type mixed SAM thin film has little or no overlapping between the HOMO level and the transmission window. Furthermore, a —CO₂H head group produces an aligned form by forming a hydrogen bond along with a neighbor molecule.

More specifically, the forming of the SAM through the ReSEM process according to an embodiment of the present disclosure is described as follows.
(I) A flat template-stripped gold (Au^{TS}) chip that was newly prepared was dipped into a degassed ethanol solution including HSC₁₅CO₂H. After the flat template-stripped gold (Au^{TS}) chip was incubated under an N₂ atmosphere at room temperature for 3 hours, an SAM bond Au^{TS} chip was rinsed by ethanol.
(II) Next, a generated mixed SAM was dipped into a 1 mM ethanol solution including HSCₙ. After incubated under an N₂ atmosphere at room temperature for 3 hours, the generated mixed SAM was rinsed by ethanol.
(III) The same step was repeated by an ethanol solution of 1 mM HSC₁₅CO₂H for 18 hours.

The last two steps are defined as one cycle in the ReSEM process. The cycle is repeated until V_{BD} reaches a stable period and an r⁺ value is maximized or becomes similar to the value of a pure HSC₁₅CO₂H SAM.

In the experimental example of the present disclosure, after a junction having an Au^{TS}/SAM//Ga₂O₃/EGaIn (“/” and “//” correspond to sharing and a Van Der Waals contact, respectively) structure was formed, a breakdown voltage was checked.

The length of an optimal alkyl chain that permits the highest breakdown voltage as high as possible with respect to an HSCₙ reinforcement molecule was determined.

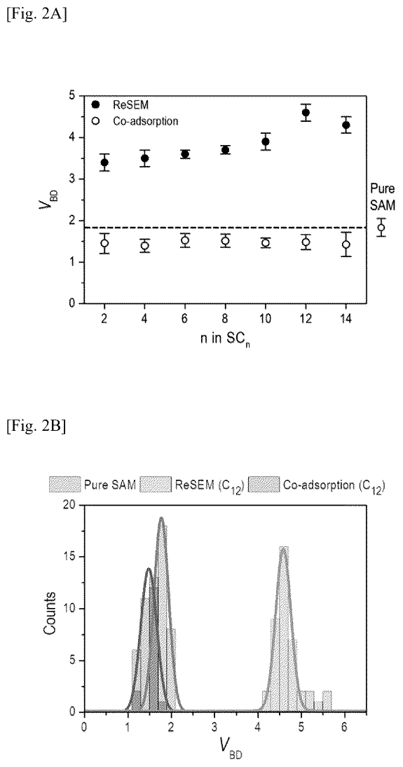

A series of heterogeneous mixed SAMs consisting of SCₙ and HSC₁₅CO₂H were manufactured through the two cycles of the ReSEM process. The breakdown voltage (V_{BD}) of the heterogeneous mixed SAM was checked by using an electrode made of eutectic Ga—In (EGaIn) covered with Ga₂O₃. A single component HSC₁₅CO₂H SAM having the breakdown voltage (V_{BD}) of about 1.8 V was tested (FIG. 2A).

The SCₙ—HSC₁₅CO₂H mixed SAM formed through the ReSEM process showed an improved breakdown voltage (V_{BD}). An overall increase trend of the breakdown voltage (V_{BD}) can be seen as the length n of the alkyl chain of the SCₙ reinforcement molecule is increased to 12 (FIG. 2B).

The mixed SAM of SC₁₂ showed that the breakdown voltage (V_{BD}) had the highest value of 4.6 V, which is 2.6 times higher than that of the pure HSC₁₅CO₂H SAM. When the length n of SCₙ is increased to 14, the value of the breakdown voltage (V_{BD}) is reduced. The reason for this is that a long alkyl chain of SCₙ hinders a hydrogen bond between carboxyl groups or significant phase separation occurs. Accordingly, from a viewpoint of electrical stability, the length n of the alkyl chain of the SCₙ reinforcement molecule according to an embodiment of the present disclosure may be 2 to 12, preferably 10 to 12.

Furthermore, additional experiments revealed that a similar mixed SAM manufactured through the existing co-adsorption had a lower breakdown voltage than the ReSEM-based SAM according to an embodiment of the present disclosure and a single HSC₁₅CO₂H SAM. The reason for this is that the ReSEM-processed mixed SAM has similar co-adsorbed mixing and a more firm and packed structure compared to a single SAM.

As a result, this means that through the measurement of the breakdown voltage (V_{BD}), the mixed SAM formed by the ReSEM process according to an embodiment of the present disclosure has a lower electrical and chemical defect level than the existing single SAM and co-adsorption mixed SAM.

Next, in an experiment example of the present disclosure, reduction and desorption analysis was performed in order to evaluate the surface density and stability of an SAM according to an embodiment of the present disclosure.

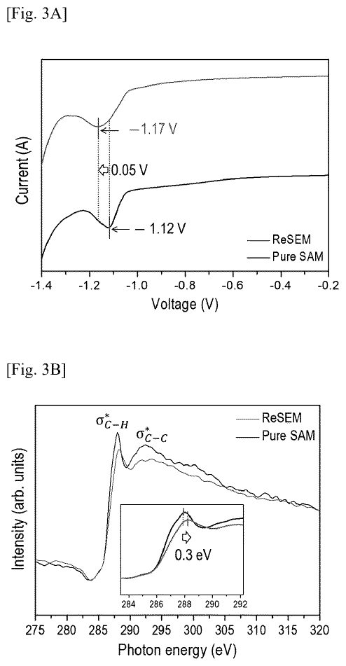

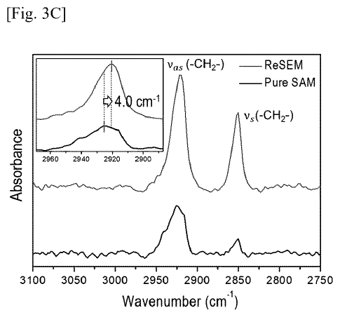

FIG. 3A illustrates circulation voltage current curves of a single HSC₁₅CO₂H SAM and an SC₁₂—HSC₁₅CO₂H heterogeneous mixed SAM formed by the ReSEM process according to an embodiment of the present disclosure.

The single HSC₁₅CO₂H SAM showed a desorption peak at −1.12 V. In the case of the SC₁₂—HSC₁₅CO₂H heterogeneous mixed SAM formed by the ReSEM process according to an embodiment of the present disclosure, the desorption peak was moved to a negative potential by 0.05 V.

It may be seen that such a movement shows that a lateral mutual interaction between the modules of the SC₁₂—HSC₁₅CO₂H heterogeneous mixed SAM is stronger than that of the pure single SAM. The single desorption peak monitored in the SC₁₂—HSC₁₅CO₂H heterogeneous mixed SAM clearly shows that the matrix molecule and the reinforcement molecule were uniformly mixed.

Furthermore, in an SC₁₂—HSC₁₅CO₂H mixed SAM (a mole ratio 5:5 in a solution) generated through co-adsorption not the ReSEM process, the desorption peak was moved in a positive direction by about 0.07 V compared to the pure single SAM, which shows that the SC₁₂—HSC₁₅CO₂H mixed SAM has smaller packing than the pure single SAM.

Such results are matched with the measurement trend of the breakdown voltage. A surface coverage ratio of the SC₁₂—HSC₁₅CO₂H heterogeneous mixed SAM formed by the ReSEM process according to an embodiment of the present disclosure is 1.3×10⁻¹⁰ mol/cm², which is 1.4 times higher than that of the single HSC₁₅CO₂H SAM (9.4×10⁻¹¹ mol/cm²).

As a result, the results show that the reinforcement molecule according to an embodiment of the present disclosure increases the density of molecules by effectively filling a pinhole defect within a single layer and as a result, the SC₁₂—HSC₁₅CO₂H heterogeneous mixed SAM formed by the ReSEM process according to an embodiment of the present disclosure has excellent electrical and chemical stability.

Next, in the experimental example of the present disclosure, a near edge X-ray absorption microstructure (NEXAFS) and infrared reflection absorption spectroscopy (IRRAS) of the SAM according to an embodiment of the present disclosure were checked.

FIG. 3B is an NEXAFS spectrum in a carbon K-edge. It may be seen that a resonance peak of the SC₁₂—HSC₁₅CO₂H heterogeneous mixed SAM formed by the ReSEM process according to an embodiment of the present disclosure is 0.3 eV higher than that of the single HSC₁₅CO₂H SAM.

This shows that the single HSC₁₅CO₂H SAM includes a disordered phase due to an asymmetrical defect of the alkyl chain compared to the SC₁₂—HSC₁₅CO₂H heterogeneous mixed SAM formed by the ReSEM process according to an embodiment of the present disclosure. Such a conclusion is further supported by a change in the lean angle (α, °) of the alkyl backbone. The value α of the single HSC₁₅CO₂H SAM is 39°±0.45°, which is slightly higher than 37°±0.10° of the SC₁₂—HSC₁₅CO₂H heterogeneous mixed SAM formed by the ReSEM process according to an embodiment of the present disclosure.

In the infrared reflection absorption spectroscopy (IRRAS) spectrum (FIG. 3C), the single HSC₁₅CO₂H SAM shows an asymmetrical methylene stretching (νₐₛ(˜CH₂—)) band having a higher frequency than that of the SC₁₂—HSC₁₅CO₂H heterogeneous mixed SAM formed by the ReSEM process according to an embodiment of the present disclosure by 4.0 cm⁻¹. This shows that the single HSC₁₅CO₂H SAM has a low crystalline structure having increased asymmetrical defects compared to the SC₁₂—HSC₁₅CO₂H heterogeneous mixed SAM formed by the ReSEM process according to an embodiment of the present disclosure.

The results mean that a Van Der Waals interaction between the matrix molecule and reinforcement molecule, which is improved through the ReSEM process according to an embodiment of the present disclosure, improves the packing characteristic of the single layer. This is matched with the results obtained in the reduction and desorption and NEXAFS experiments.

In contrast, the SC₁₂—HSC₁₅CO₂H mixed SAM generated by the co-adsorption not the ReSEM process shows a νₐₛ (—CH₂—) band that is very similar to that of the single HSC₁₅CO₂H SAM. This shows that the packing characteristic of an SAM cannot be improved by the existing co-adsorption process, and is matched with the measurement experiment results of the breakdown voltage.

Next, in the experimental example of the present disclosure, molecular junction data according to an embodiment of the present disclosure were checked.

As a voltage increased from |1.0 V| to |4.0 V|, a dynamic change of r in its size and polarity was checked.

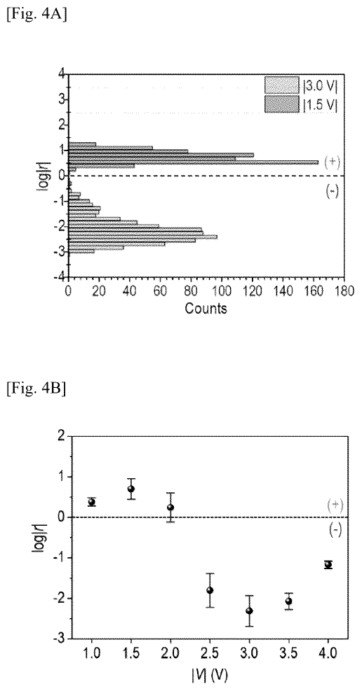

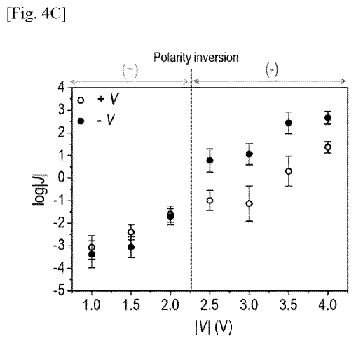

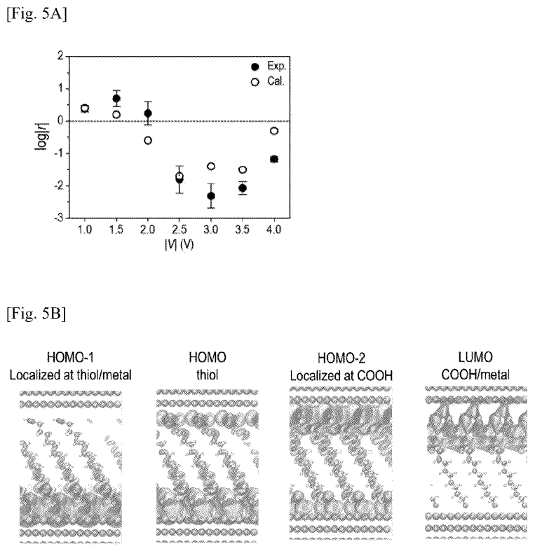

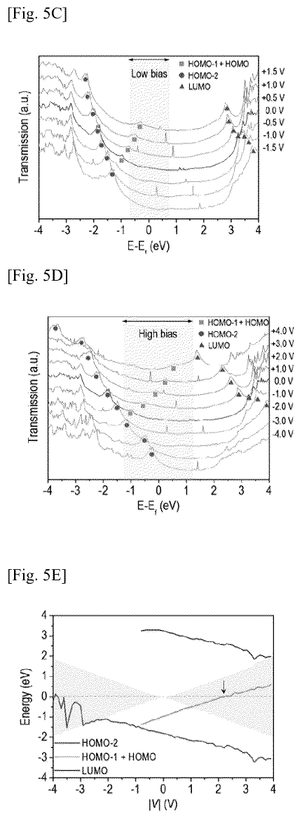

Insignificant rectification of r≈2 at |1.0 V| was slightly improved to r≈5 as the voltage increased to |1.5 V|, but a positive polarity was not changed. As the voltage further increased, the rectification (r≈1.0) disappeared at |2.0 V|. At next |3.0 V|, significantly high rectification of an opposite polarity (r≈0.005; 1/r≈200) appeared (FIG. 4A).

FIG. 4B is a summary of an overall trend of log |r| as a function of |V|. A crossing voltage the polarity of which is inverted is about |2.0 V|. The value of log |J(−V)| prior to the crossing voltage more sharply increases than the value of log |J(+V)|, so the rectification disappears. After the crossing voltage, the trend of log |J| continues, and thus significant rectification having the inverted polarity is induced (FIG. 4C). Considering that the range of a current that flows across the junction is determined depending on a degree of overlapping between the accessible MO energy level and the transmission window, the number and/or type of accessible MOs are dynamically changed as a function of the size and polarity of an applied voltage.

As described above, the high rectification characteristic of the electrically inactive pure organic molecule (i.e., alkyl carboxylic acid) that has no rectification characteristic is an exceptional phenomenon.

Next, a wide change in the current-voltage characteristic and dynamic rectification was calculated by using NEGF-DFT. The calculation was based on the following assumption and simplification.

In the calculation, it is assumed that a process induced by a high bias voltage, that is, current inductivity, is neglected, static NEGF-DFT calculation may be approximate to a measured current value because the current inductivity increases a local temperature of a molecule in a transport path and helps the molecule to falls outside a potential energy minimum value, but has a limited influence on a minimum energy structure itself, and the reinforcement molecule HSC₁₂ does not greatly interact with an upper electrode compared to the matrix molecule. Accordingly, considering that the calculation is not related to the transfer of electrons, it is expected that the calculation of NEGF-DFT for the single HSC₁₅CO₂H SAM will capture the current-voltage characteristic of the SC₁₂—HSC₁₅CO₂H heterogeneous mixed SAM formed by the ReSEM process according to an embodiment of the present disclosure. Finally, for the simplicity of the results of the calculation, in an effect in which EGaIn is substituted with Au in the upper electrode, a low work function of EGaIn lowers the entire MO level by increasing the Fermi level of a system, and the crossing voltage of the rectification rate is moved to a higher side than that of the experimental results because the location of a HOMO-2 level is lowered, but there is no change in the results.

The rectification rate calculated in the NEGF-DFT current-voltage characteristic well reappeared the experimental trend. Specifically, positive rectification was checked at a low bias voltage, and negative rectification was checked at a high bias voltage (FIG. 5A)

The height of the transmission peak was low because HOMO and HOMO-1 levels were placed near the Fermi level at 0 V and a wave function was placed at the portion of a thiol group anchor. HOMO-2 and LUMO levels were properly delocalized, and greatly distributed to a COOH portion, thereby providing a transmission channel for the junction (FIG. 5B).

Next, the dependence of the transmission function and PDOS on a bias illustrates the origin of polarity inversion and a change of a rectification size. FIGS. 5C and 5D illustrate a change in the transmission peak as a function of an external bias voltage. In the applied external bias, thiolate localization HOMO and HOMO-1 levels follow the Fermi level of the lower electrode, whereas COOH localization HOMO-2 and LUMO levels follow the Fermi level of the upper electrode. In a low bias region, the dependence of the transmission function on the bias illustrates that the HOMO and HOMO-1 levels enter the transmission window at the positive bias (FIGS. 5C and 5E) and are matched with the Fermi level at 2.0 V (refer to a black arrow in FIG. 5E). In contrast, the HOMO and HOMO-1 levels fall outside the Fermi level at the negative bias. A change of MO energy according to such a bias describes experimental monitoring because a rectification rate is slightly increased at the positive polarity (FIG. 5A).

An MO level that is far away from the Fermi level at a zero bias is gradually more important in a high bias region (FIG. 5D). In general, when a molecule structure is asymmetrical, the frontier MO level shows an asymmetrical distribution and generates a dipole moment. In contrast, a deeper MO level tends to be delocalized. In a high negative bias of −2.5 V or more, the MO level has higher conductivity than the HOMO level. At the zero bias, the top of the peak of the HOMO-2 level placed at −2 eV enters the transmission window (FIGS. 5D and 5E). Accordingly, this describes the inversion of the polarity monitored in the high bias experiments (FIG. 5A). The reason why the rectification rate was reduced over |3.5V| is that the LUMO level entered a bias window at a high positive bias (FIG. 5E).

The role of non-frontier molecular orbital, such as HOMO-2 that is not commonly important in tunneling transport plays a decisive role in rectifying in a high bias, which was achieved by using the ReSEM process according to an embodiment of the present disclosure due to the arrangement of a deep energy level. The crossing voltage (|1.7 V|) determined in the calculation is slightly lower than the crossing voltage (|≈2.0 V.|) determined in the experiment. Such a deviation is caused by the effect in which EGaIn was substituted with Au in the upper electrode for the simplification of the results of the calculation. The low work function of EGaIn raises the Fermi level of a system, so that the entire MO level is lowered. As a result, the experimentally determined crossing voltage is moved to a high value compared to the results of the calculation. However, an overall trend of the rectification in the calculation is quantitatively matched with the trend monitored in the experiment.

Next, the results were adjusted based on the results of the calculation by additionally performing normalized differential conduction (NDC) analysis.

When a parabola NDC peak appears in the NDC analysis, it proves that the molecular orbital energy level enters the transmission window. The parabola NDC peak is monitored at +1.5 V, and is not monitored at −1.5 V. This means that the HOMO and HOMO-1 levels enter the transmission window at +1.5 V along with the results of the calculation and there is nothing at −1.5 V. This describes that proper rectification having the positive polarity appears at |±1.5 V|. As the external voltage rises to |±2.0 V| at which the polarity of rectification is inverted, a significant NDC peak appears in the negative bias. This means that the HOMO-2 level has entered the transmission window. From the NDC results, it may be seen that the sub-HOMO plays an important role in the dynamic change of rectification because the NDC results are generally matched with the results of the calculation.

Furthermore, as the results of the analysis of ultraviolet photoelectron spectroscopy for the single HSC₁₅CO₂H SAM and the SC₁₂—HSC₁₅CO₂H heterogeneous mixed SAM formed by the ReSEM process according to an embodiment of the present disclosure, the HOMO level and the work function were similar in the single HSC₁₅CO₂H SAM (−1.51 and 3.82 eV) and the SC₁₂—HSC₁₅CO₂H heterogeneous mixed SAM (−1.46 and 3.86 eV) formed by the ReSEM process according to an embodiment of the present disclosure. This shows that the ReSEM process improves the packing characteristic of the SAM even without greatly affecting an electronic structure.

As described above, as the results of the check through various experimental examples of the present disclosure, it can be seen that the SC₁₂—HSC₁₅CO₂H heterogeneous mixed SAM formed by the ReSEM process based on a surface exchange reaction according to an embodiment of the present disclosure greatly improves electrical stability and thus a thin film layer can be applied as an adjustable rectification device in the polarity and the size of rectification.

In the embodiments of the present disclosure, if a thin film layer is formed through the ultra molecular engineering, a new electrical characteristic can be induced even in an electrically inactive molecule that is structurally simple. If the ultra molecular engineering is used, there is an opportunity that a cheap and accessible electronic device can be produced by using simple organic molecules.

In the embodiments of the present disclosure, there is of great significance in that a new electrical characteristic can be induced through the extension of the transmission window.

An SAM is an ultra thin organic monomolecular thin film of several nano meters (<2 nm). Accordingly, a large-area film is manufactured by using the SAM, when the film inevitably has a defect structure. Such an ultra molecular defect acts as a disadvantage in that performance tests are inevitably performed on the SAM only at a low voltage.

Furthermore, in the research of molectronics, in general, an SAM is actually researched only at the breakdown voltage V_{BD} of about 1.0 V. The size of the breakdown voltage determines the width of the transmission window and further determines the type and number of energy levels that may be accessed. Accordingly, the fact that the SAM is permitted at only a low voltage acts as a very great disadvantage in the research of molectronics.

Accordingly, in the existing molelectropnic device, complicated organic synthesis is involved in order to control the energy level within a limited transmission window. In the embodiments of the present disclosure, an SAM to which a high voltage may be applied through ultra molecular control can be easily provided. Unlike in the existing technology, a new energy level can be included in the transmission window. This may be a strategy which can induce a new electrical characteristic.

Furthermore, in the embodiments of the present disclosure, the mixed SAM is manufactured by using the ReSEM method, and an SAM system capable of withstanding a high voltage is provided. In the SAM system according to the embodiments of the present disclosure, the breakdown voltage V_{BD} is increased by about 2.5 to 3.5 times compared to the single SAM and the co-adsorption-based mixed SAM that is commonly used in a conventional technology. A maximum breakdown voltage is driven up to 5.6 V.

While various embodiments have been described above, it will be understood to those skilled in the art that the embodiments described are by way of example only. Accordingly, the disclosure described herein should not be limited based on the described embodiments.

What is claimed is:

1. A heterogeneous supramolecular-mixed self-assembled monolayer (SAM) thin film comprising a plurality of matrix molecules that is adjacently arranged in parallel and a reinforcement molecule packed between the plurality of matrix molecules,
wherein each of the matrix molecule and the reinforcement molecule is a molecule not having electrical activity,
the matrix molecule is represented by Chemical Formula 1, and
the reinforcement molecule is represented by Chemical Formula 2,
the heterogeneous supramolecular-mixed SAM thin film is formed through a repeated surface exchange of molecules (ReSEM) process, and
when the heterogeneous supramolecular-mixed SAM thin film is formed through the ReSEM process, the matrix molecule has electrical activity:
HS—(CₘH₂₊₁)—COOH [Chemical Formula 1]
HS—(CₘH₂ₘ₊₁) [Chemical Formula 2]
In Chemical Formula 1 and Chemical Formula 2, each of n and m is an integer of 1 to 20, wherein n>m.

2. The heterogeneous supramolecular-mixed SAM thin film of claim 1, wherein:
the matrix molecule represented by Chemical Formula 1 is HS—(C₁₅H₃₁)—COOH, and
the reinforcement molecule represented by Chemical Formula 2 is HS—(C₁₂H₂₅).

3. The heterogeneous supramolecular-mixed SAM thin film of claim 1, wherein the heterogeneous supramolecular-mixed SAM thin film is formed by the ReSEM process comprising following steps:
(I) a step of forming a self-assembled monolayer (SAM) composed of the matrix molecule on a substrate by using the matrix molecule represented by Chemical Formula 1;
HS—(CₙH₂₊₁)—COOH [Chemical Formula 1]
(II) a step of forming an intermediate-mixed SAM by inducing a substitution reaction within a surface of the SAM by dipping the SAM produced through the step (I) in a solution of the reinforcement molecule represented by Chemical Formula 2;
HS—(CₘH₂ₘ₊₁) [Chemical Formula 2]
(III) a step of forming an interstitial-mixed SAM having packing enhanced by dipping the intermediate-mixed SAM formed through the step (II) into the solution of the matrix molecule again; and
(IV) a step of forming an interstitial-mixed SAM thin film having an ultra molecular defect minimized by inducing n ReSEM cycles by repeating the steps (II) to (III) n times (wherein the n is an integer equal to or greater than 2),
wherein in Chemical Formula 1 and Chemical Formula 2, each of n and m is an integer of 1 to 20, wherein n>m.

4. The heterogeneous supramolecular-mixed SAM thin film of claim 3, wherein the substrate is a flat template-stripped metal chip.

5. A molecule electronic device comprising the heterogeneous supramolecular-mixed SAM thin film of claim 1, the molecule electronic device comprising:
an upper electrode;
a lower electrode that faces the upper electrode; and
a molecular layer formed on the lower electrode,
wherein the molecular layer is the heterogeneous supramolecular-mixed SAM thin film manufactured by the manufacturing method of claim 1, and
the upper electrode is a liquid metal eutectic gallium-indium (EGaIn) alloy-based electrode.

6. The molecule electronic device of claim 5, wherein a size of a breakdown voltage (V_{BD}) of the molecule electronic device is |2.0V| to |4.6 V|.

7. The molecule electronic device of claim 6, wherein the molecule electronic device is a molecular rectification device that performs a molecular rectification action.
